(19) United States
(12) Patent Application Publication
(10) Pub. No.: US 2018/0254550 A1
(43) Pub. Date: Sep. 6, 2018

(54) ANTENNA DEVICE

(71) Applicant: Panasonic Corporation, Osaka (JP)

(72) Inventors: TOMOHIRO MURATA, Kanagawa (JP); JUNJI SATO, Tokyo (JP)

(21) Appl. No.: 15/899,678

(22) Filed: Feb. 20, 2018

(30) Foreign Application Priority Data
Mar. 1, 2017 (JP) 2017-038379

(51) Int. Cl. H01Q 1/38; H01Q 1/24; H01L 23/66; H01Q 1/22; H01Q 19/10

(52) U.S. Cl. CPC H01Q 1/38; H01Q 1/243; H01L 23/66; H01L 2924/14; H01Q 19/10; H01L 2223/6677; H01Q 1/2283

(57) ABSTRACT

An antenna device includes: a dielectric substrate having a first surface and a second surface; a semiconductor substrate disposed above the first surface of the dielectric substrate and having a third surface and a fourth surface that faces the dielectric substrate; an integrated circuit disposed on the fourth surface of the semiconductor substrate; a radiator disposed on the fourth surface of the semiconductor substrate; a reflector disposed at a position where projection of the radiator along a radiation direction of an electromagnetic wave radiated from the radiator falls on the third surface of the semiconductor substrate; and one or more directors disposed at a position where projection of the radiator along the radiation direction falls on the dielectric substrate.

### BACKGROUND

### 1. Technical Field

The present disclosure relates to an antenna device.

### 2. Description of the Related Art

Antenna devices having a semiconductor integrated circuit, such as complementary metal oxide semiconductor (CMOS), and an antenna integrated on one same substrate are known. An antenna integrated on the same substrate as a semiconductor integrated circuit is called an on-chip antenna. On-chip antennas are advantageous for reducing the size and/or price of communication or radar modules, for example.

As an example, an on-chip patch antenna fabricated with CMOS technology and operating in the 60 GHz band is disclosed by T. Hirano, K. Okada, J. Hirokawa, and M. Ando, “60 GHz On-Chip Patch Antenna Integrated in a 0.18-μm CMOS Technology”, Proceedings of the International Symposium on Antennas & Propagation (ISAP) 2012, pp.62-65.

### SUMMARY

While an on-chip antenna is advantageous for size reduction, it has low antenna gain because an electromagnetic wave radiated from the on-chip antenna propagates in the semiconductor substrate having large propagation loss.

One non-limiting and exemplary embodiment facilitates providing an antenna device that can increase the antenna gain.

In one general aspect, the techniques disclosed here feature an antenna device including: a dielectric substrate having a first surface and a second surface; a semiconductor substrate disposed above the first surface of the dielectric substrate and having a third surface and a fourth surface that faces the dielectric substrate; an integrated circuit disposed on the fourth surface of the semiconductor substrate; a radiator disposed on the fourth surface of the semiconductor substrate; a reflector disposed at a position where projection of the radiator along a radiation direction of an electromagnetic wave radiated from the radiator falls on the third surface of the semiconductor substrate; and one or more directors disposed at a position where projection of the radiator along the radiation direction falls on the dielectric substrate.

According to an aspect, the present disclosure achieves increased antenna gain.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1A is a plan view showing an example of a conventional on-chip antenna;

FIG. 1B is a sectional view taken along line A1-A2 in FIG. 1A;

FIG. 2A is a plan view showing the structure of an antenna device according to a first embodiment of the present disclosure;

FIG. 2B is a sectional view of the antenna device taken along line A1-A2 in FIG. 2A;

FIG. 2C is a sectional view of the antenna device taken along line A3-A4 in FIG. 2B, showing a semiconductor substrate;

FIG. 2D is a sectional view of the antenna device taken along line A3-A4 in FIG. 2B, showing a dielectric substrate;

FIG. 3A is an enlarged view of a part around a radiator of the antenna device;

FIG. 3B shows an example of an antenna device as a comparative structure;

FIG. 3C shows an example of an antenna device as a comparative structure;

FIG. 4 is a diagram showing the characteristics of the antenna gain of the antenna device according to the first embodiment of the present disclosure;

FIG. 5A shows the structure of an antenna device according to the first embodiment of the present disclosure;

FIG. 5B shows the structure of an antenna device according to the first embodiment of the present disclosure;

FIG. 6A shows an example of an antenna device as a comparative structure;

FIG. 6B shows an example of an antenna device as a comparative structure;

FIG. 7 is a diagram showing antenna gain characteristics compared for different directions in which a wiring extends;

FIG. 8A shows the structure of an antenna device according to the first embodiment of the present disclosure;

FIG. 8B shows the structure of an antenna device according to the first embodiment of the present disclosure;

FIG. 9 is a diagram showing the relationship between minimum distance dmin and maximum antenna gain;

FIG. 10 shows the structure of an antenna device according to a second embodiment of the present disclosure;

FIG. 11 shows the structure of an antenna device according to a third embodiment of the present disclosure;

FIG. 12 shows the structure of an antenna device according to a fourth embodiment of the present disclosure;

FIG. 13A shows an exemplary variation of the antenna device according to the fourth embodiment of the present disclosure;

FIG. 13B shows another exemplary variation of the antenna device according to the fourth embodiment of the present disclosure;

FIG. 14A shows the structure of an antenna device according to a fifth embodiment of the present disclosure; and

FIG. 14B shows an exemplary variation of the antenna device according to the fifth embodiment of the present disclosure.

### DETAILED DESCRIPTION

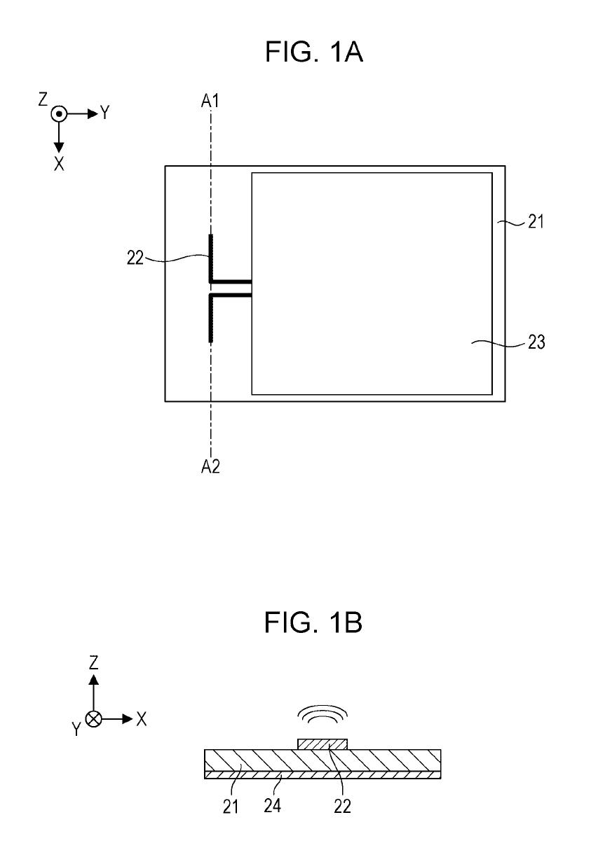

FIG. 1A is a plan view showing an example of a conventional on-chip antenna. FIG. 1B is a sectional view taken along line A1-A2 in FIG. 1A in an X-Z plane including an on-chip antenna 22.

In FIGS. 1A and 1B, the on-chip antenna 22 and an integrated circuit 23 are integrated on a same plane on a semiconductor substrate 21. A reflector 24 made of conductor is disposed on a surface of the semiconductor substrate 21 on the opposite side of the surface on which the on-chip antenna 22 is formed.

An electromagnetic wave radiated by the on-chip antenna 22 to the semiconductor substrate 21 is reflected off the reflector 24 to be radiated upward (in the positive direction of the Z-axis).

An on-chip antenna is often disposed in an integrated circuit on a semiconductor substrate, which is expensive per unit area, and thus can lead to increased cost when it is large-sized and hence occupies a wide area. For this reason, on-chip antennas do not find many applications to signals of a relatively long wavelength, for example, in a microwave band (low-frequency signals). On the other hand, on-chip antennas are often utilized for high-frequency signals because an antenna can be of a small size with signals in a millimeter wave/terahertz wave band (high-frequency signals), for example.

In a wireless module that includes an antenna substrate having an antenna for high-frequency signals and a semiconductor substrate having an integrated circuit, wires or bumps serving as connections are interposed between the antenna substrate and the semiconductor substrate, for example. Such a wireless module suffers from reduced antenna gain due to propagation loss of signals at the connections.

An antenna device with a semiconductor integrated circuit and an antenna integrated on the same semiconductor substrate can eliminate connections and thus can deter reduction in antenna gain due to propagation loss of signals at the connections.

Since an on-chip antenna is mounted on a semiconductor substrate together with an integrated circuit, however, much of the electromagnetic wave radiated from the on-chip antenna propagates through the semiconductor substrate. Consequently, an antenna device employing an on-chip antenna suffers from reduction in antenna gain due to propagation loss in the semiconductor substrate.

The present disclosure has been made in view of this challenge, based on the recognition that the antenna gain is increased by disposing an element for directing an electromagnetic wave in a desired radiation direction so that propagation loss in the semiconductor substrate is suppressed.

Embodiments of the present disclosure will be now described in detail with reference to drawings. The embodiments described below are merely examples and are not intended to limit the present disclosure.

### First Embodiment

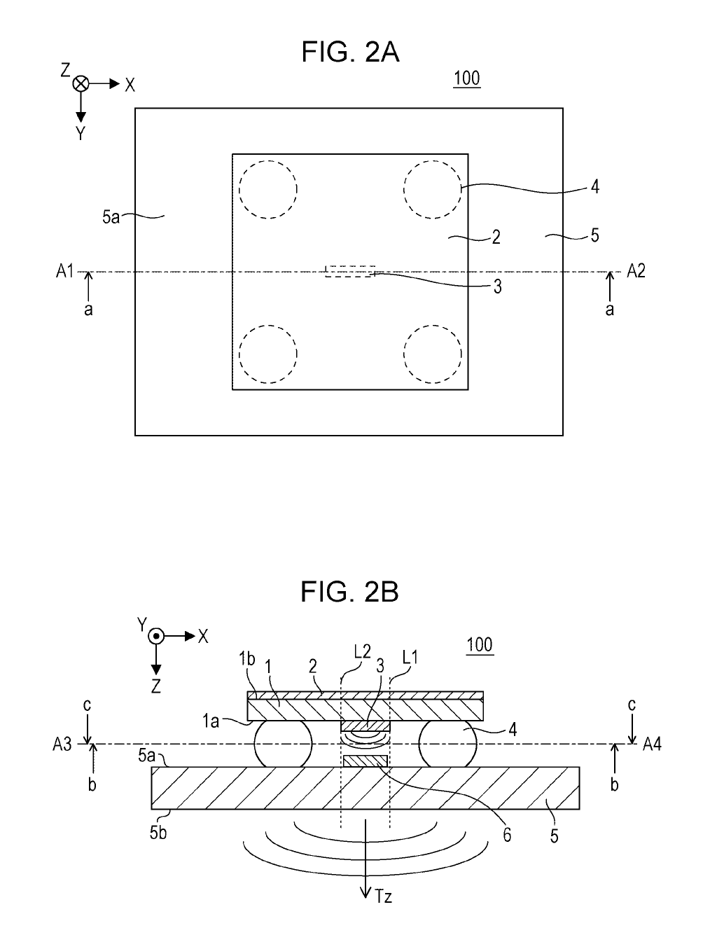

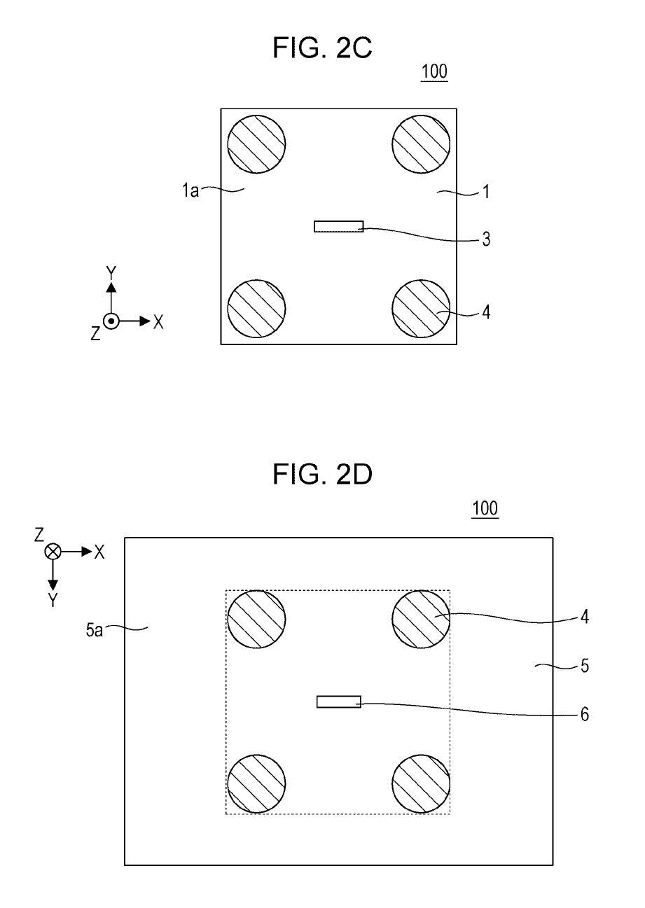

FIG. 2A is a plan view showing a structure of an antenna device 100 according to a first embodiment of the present disclosure. FIG. 2B is a sectional view of the antenna device 100 taken along line A1-A2 in FIG. 2A (in the positive direction of the Y-axis). FIG. 2C is a sectional view of the antenna device 100 taken along line A3-A4 in FIG. 2B, showing a semiconductor substrate 1 as seen from the direction of arrow b in FIG. 2B (the positive direction of the Z-axis). FIG. 2D is a sectional view of the antenna device 100 taken along line A3-A4 in FIG. 2B, showing a dielectric substrate 5 as seen from the direction of arrow c in FIG. 2B (the negative direction of the Z-axis).

As shown in FIG. 2B, the antenna device 100 includes the semiconductor substrate 1, a reflector 2, a radiator 3, bumps 4, the dielectric substrate 5, and a director 6.

On a surface 1a of the semiconductor substrate 1, a CMOS integrated circuit (not shown), for example, is disposed. At least part of the integrated circuit performs signal processing for a frequency in a high-frequency band (for example, from 50 GHz to 10 THz, inclusive) including a millimeter wave/terahertz wave band. The integrated circuit may perform signal processing on baseband, for example.

The radiator 3 is disposed on the surface 1a of the semiconductor substrate 1, that is, the same surface on which the integrated circuit is positioned. The radiator 3 radiates an electromagnetic wave of a signal processed in the integrated circuit in radiation direction Tz (the positive direction of the Z-axis). The radiator 3 may take the form of a dipole antenna, which is an electric-field antenna, for example. The length of the radiator 3 is about half the effective wavelength, for example. For the sake of simplicity, FIGS. 2A to 2C represent the radiator 3 as a rectangle and also do not show feeder lines connected with the radiator 3 and the like. The integrated circuit on the semiconductor substrate 1 is provided at a location where effect on the radiation characteristics is small.

The reflector 2 is evenly disposed on a surface 1b of the semiconductor substrate 1 on the opposite side of the surface 1a. The reflector 2 reflects the electromagnetic wave radiated from the radiator 3 to the surface 1b along the radiation direction Tz (in the positive direction of the Z-axis).

The radiation intensity of the electromagnetic wave in the radiation direction Tz can be increased by taking into consideration the interval between the reflector 2 and the radiator 3, that is, the thickness of the semiconductor substrate 1.

Although the reflector 2 is evenly disposed on the surface 1b in the example shown FIG. 2B, it may be disposed on the surface 1b in any region that includes a position along the radiation direction Tz of the electromagnetic wave radiated from the radiator 3. A position along the radiation direction Tz refers to a position that encompasses an area on the surface 1b in which projection of the radiator 3 along the radiation direction Tz (in the positivedirection of the Z-axis) falls, for example. For example, a position along the radiation direction Tz refers to a position that encompasses an area in which straight lines L1 and L2 extended along the the opposite direction to radiation direction Tz and passing through the ends of the radiator 3 intersect with the surface 1b. The width of the reflector 2 in the Y-axis direction is larger than the width of the radiator 3 in the Y-axis direction, for example.

The bumps 4 connect the semiconductor substrate 1 with the dielectric substrate 5 and are formed of substantially spherical solders, for example. In FIG. 2C, the bumps 4 are provided at positions surrounding the radiator 3 as an example.

The dielectric substrate 5 is a substrate on which the semiconductor substrate 1 is mounted. The dielectric substrate 5 has a surface 5a (the front side) facing the surface la of the semiconductor substrate 1 and a surface 5b (the underside) opposite the surface 5a. On the dielectric substrate 5, a power supply circuit (not shown) and a control circuit (not shown) for driving the integrated circuit on the semiconductor substrate 1 are disposed, for example. The dielectric substrate 5 is connected with the semiconductor substrate 1 via the bumps 4.

The dielectric substrate 5 also functions as a radome for covering the surface la of the semiconductor substrate 1 on which the radiator 3 is disposed.

The director 6 is disposed at a position along the radiation direction Tz on the surface 5a of the dielectric substrate 5, which faces the semiconductor substrate 1. A position along the radiation direction Tz refers to a position that encompasses an area on the surface 5a in which projection of the radiator 3 along the radiation direction Tz (along the Z-axis direction) falls, for example. For example, a position along the radiation direction Tz refers to a position that encompasses the area in which the straight lines L1 and L2 in FIG. 2B intersect with the surface 5a. The director 6 is a passive element and is not connected with the circuits disposed on the dielectric substrate 5 (for example, a power supply circuit and a control circuit). The longitudinal direction of the director 6 is parallel with the longitudinal direction of the radiator 3.

The radiation intensity of the electromagnetic wave in the radiation direction Tz can be increased by taking into consideration the length of the director 6 and the interval between the radiator 3 and the director 6.

When inferring the director 6 and the radiator 3 according to the present disclosure from a Yagi-Uda antenna with a radiator, a reflector, and a director, the length of the director 6 would be equal to the length of the radiator 3 (that is, about half the effective wavelength) reduced by about 5% to 15%. The interval between the director 6 and the radiator 3 is about ⅛ to ¼ of the effective wavelength.

For formation of the director 6 and the radiator 3 with such a length and an interval on the antenna device 100, the operation frequency of the antenna device 100, that is, the frequency of the electromagnetic wave it radiates, is set in a millimeter wave or terahertz band having a relatively short wavelength. For example, the frequency may be on the order of from 50 GHz where the wavelength in vacuum, λ₀, is 6 mm, to 10 THz where the wavelength in vacuum, λ₀, is 0.03 mm, inclusive.

In the antenna device 100, the electromagnetic wave radiated from the radiator 3 in the radiation direction Tz and the electromagnetic wave reflected by the reflector 2 are combined and reach the director 6. The combined electromagnetic wave is then re-radiated from the director 6. The director 6 is an element that directs the combined electromagnetic wave in the radiation direction Tz. That is to say, in the antenna device 100, the radiator 3, the reflector 2, and the director 6 function as a single antenna.

In the antenna device 100, the director 6 is able to direct the electromagnetic wave radiated from the radiator 3 into the radiation direction Tz; thus components radiated from the radiator 3 in the opposite direction to the radiation direction Tz (the negative direction of the Z-axis) are reduced, suppressing propagation loss in the semiconductor substrate 1.

The antenna gain of the antenna device 100 discussed above is described below in comparison with those of antenna devices C1 and C2 as comparative structures.

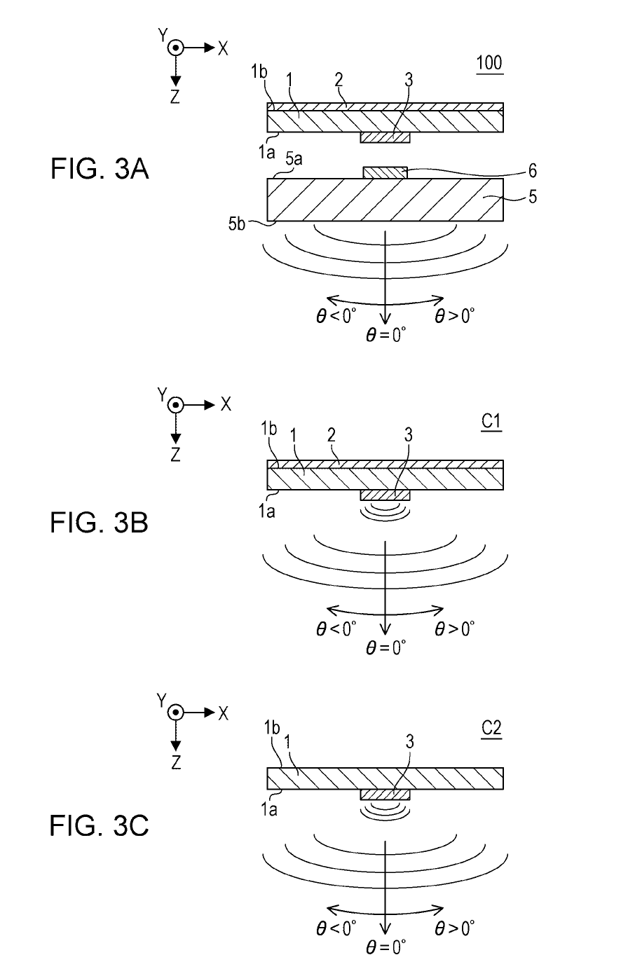

FIG. 3A is a sectional enlarged view of a part around the radiator 3 of the antenna device 100, taken in an X-Z plane including the radiator 3 and the director 6. FIG. 3B is a sectional view in an X-Z plane including the radiator 3, showing an example of the antenna device C1 as a comparative structure. FIG. 3C is a sectional view in an X-Z plane including the radiator 3, showing an example of the antenna device C2 as a comparative structure. In FIGS. 3A to 3C, components similar to those in FIG. 2B are given the same reference characters and are not described again. In FIGS. 3A to 3C, the positive and negative directions of radiation angle θ are also indicated, with the radiation direction Tz being the reference of 0°. The positive direction of radiation angle θ refers to the positive direction of the X-axis with respect to the radiation direction Tz, and the negative direction of radiation angle θ refers to the negative direction of the X-axis with respect to the radiation direction Tz.

The antenna device C1 as a comparative structure shown in FIG. 3B does not have the dielectric substrate 5 and the director 6, as opposed to the antenna device 100 shown in FIG. 3A. The antenna device C2 as a comparative structure shown in FIG. 3C does not have the dielectric substrate 5, the director 6, and the reflector 2, as opposed to the antenna device 100 shown in FIG. 3A.

In other words, in the antenna device 100 shown in FIG. 3A, the radiator 3, the reflector 2, and the director 6 function as a single antenna; in the antenna device C1 as a comparative structure shown in FIG. 3B, the radiator 3 and the reflector 2 function as a single antenna; and in the antenna device C2 as a comparative structure shown in FIG. 3C, the radiator 3 functions as a single antenna.

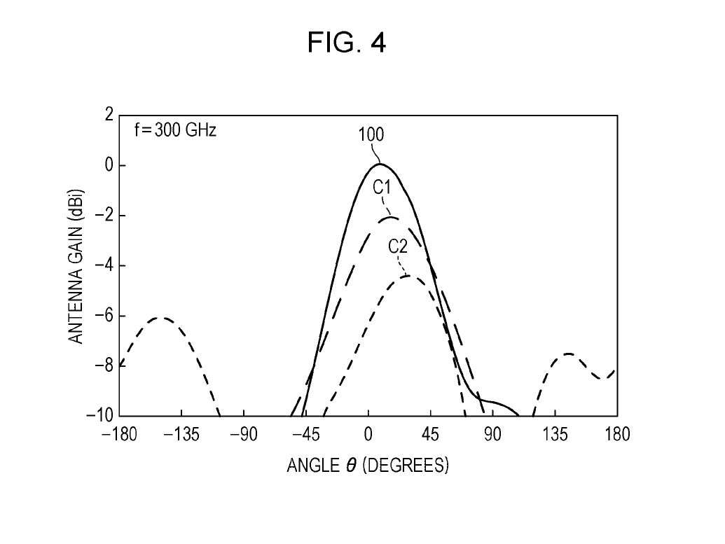

FIG. 4 is a diagram showing the characteristics of the antenna gain of the antenna device 100 according to this embodiment. In FIG. 4, the horizontal axis represents the radiation angle with the radiation direction Tz being the reference of 0°, and the vertical axis represents the antenna gain (in dBi). FIG. 4 shows the antenna gains of the antenna device 100, the antenna device C1 as a comparative structure, and the antenna device C2 as a comparative structure with respect to the radiation angle when the frequency f of the electromagnetic wave radiated is 300 GHz.

The antenna gain of the antenna device 100 shown in FIG. 4 is improved over those of the antenna devices C1 and C2 as comparative structures. For example, the maximum of the antenna gain (the maximum antenna gain) of the antenna device 100 is improved by about 2 dB over the maximum antenna gain of the antenna device C1 as a comparative structure.

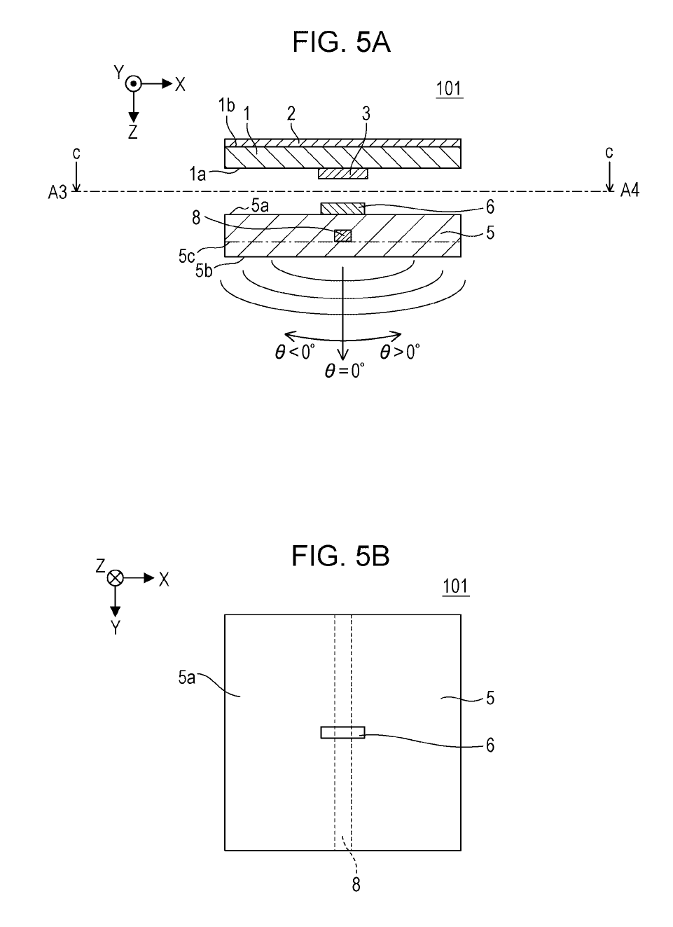

Next, the relationship between wiring of a conductor pattern provided in an inner layer of the dielectric substrate 5 and the antenna gain is described. FIGS. 5A and 5B show the structure of an antenna device 101 according to the first embodiment. In FIGS. 5A and 5B, components similar to those in FIG. 2B are given the same reference characters and are not described again. In FIGS. 5A and 5B, the positive and negative directions of radiation angle θ are also indicated, with the radiation direction Tz (the positive direction of the Z-axis) being the reference of 0°.

FIG. 5A is a sectional view of the antenna device 101 in an X-Z plane including the radiator 3 and the director 6 as with FIG. 2B. FIG. 5B is a sectional view of the antenna device 101 in an X-Y plane taken along line A3-A4 in FIG. 5A, showing the dielectric substrate 5 as seen from the direction of arrow c in FIG. 5A (the negative direction of the X-axis).

The antenna device 101 is different from the antenna device 100 in that it has a wiring 8.

The wiring 8 is disposed on an inner-layer plane 5c of the dielectric substrate 5 immediately below the director 6 and extends vertically to the longitudinal direction of the director 6 (that is, extends in the Y-axis direction). That is, the wiring 8 extends in the short direction of the director 6.

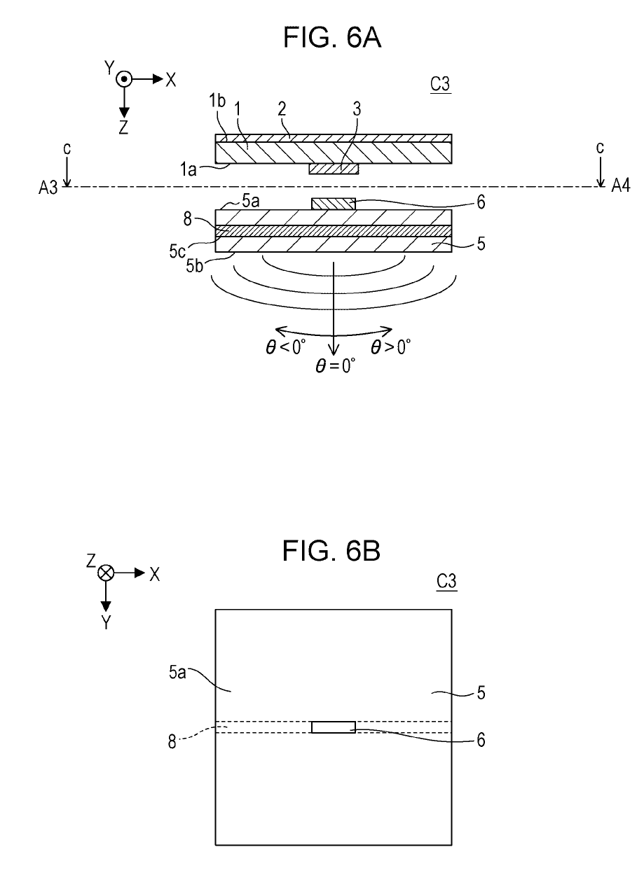

FIGS. 6A and 6B show an example of an antenna device C3 as a comparative structure. In FIGS. 6A and 6B, components similar to those in FIG. 2B are given the same reference characters and are not described again. In FIG. 6A, the positive and negative directions of radiation angle θ are also indicated, with the radiation direction Tz being the reference of 0°.

FIG. 6A is a sectional view of the antenna device C3 as a comparative structure in an X-Z plane including the radiator 3 and the director 6 as with FIG. 2B. FIG. 6B is a sectional view of the antenna device C3 in an X-Y plane along line A3-A4 in FIG. 6A, showing the dielectric substrate 5 as seen from the direction of arrow c in FIG. 6A (the negative direction of the Z-axis).

The antenna device C3 as a comparative structure is different from the antenna device 100 in that it has the wiring 8.

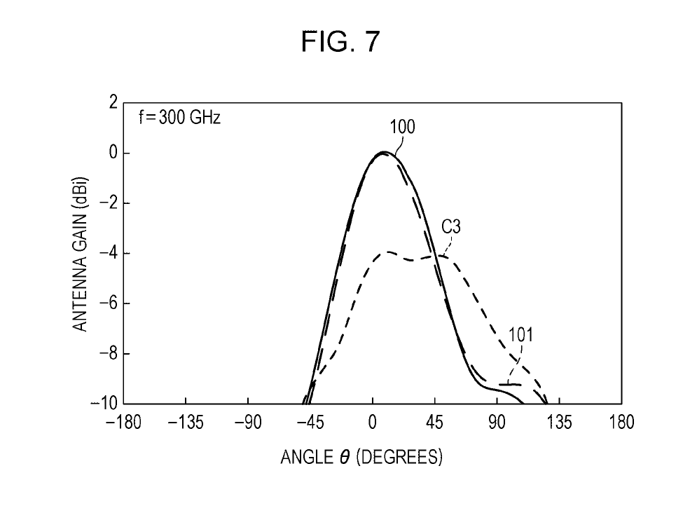

The wiring 8 is disposed on the inner-layer plane 5c of the dielectric substrate 5 immediately below the director 6 and extends parallel to the longitudinal direction of the director 6 (that is, extends in the X-axis direction). That is to say, the antenna device 101 and the antenna device C3 as a comparative structure are different in the direction in which the wiring 8 on the inner-layer plane 5c of the dielectric substrate 5 extends. Difference in antenna gain associated with difference in the direction in which the wiring 8 extends is described in FIG. 7.

FIG. 7 is a diagram showing antenna gain characteristics compared for different directions in which the wiring 8 extends. In FIG. 7, the horizontal axis represents the radiation angle with the radiation direction Tz being the reference of 0°, and the vertical axis represents the antenna gain (in dBi). FIG. 7 shows the antenna gains of the antenna device 100, the antenna device 101, and the antenna device C3 as a comparative structure with respect to the radiation angle when the frequency f of the electromagnetic wave radiated is 300 GHz. The antenna gain of the antenna device 100 shown in FIG. 7 is similar to the antenna gain of the antenna device 100 shown in FIG. 4.

The antenna gain of the antenna device 101 shown in FIG. 7 is similar to the antenna gain of the antenna device 100. In the antenna device 101, due to the fact that the wiring 8 extends in a direction vertical to the longitudinal direction of the radiator 3 (that is, extends in the Y-axis direction), overlap between the electromagnetic wave radiated from the radiator 3 and the wiring 8 is small in the field excitation direction of the electromagnetic wave, thus the radiated electromagnetic wave hardly couples with the wiring 8. Consequently, the antenna device 101 has a similar antenna gain to that of the antenna device 100.

Meanwhile, the antenna gain of the antenna device C3 as a comparative structure shown in FIG. 7 is lower than that of the antenna device 100. In the antenna device C3 as a comparative structure, due to the fact that the wiring 8 extends in a direction parallel to the longitudinal direction of the radiator 3 (that is, extends in the X-axis direction), overlap between the electromagnetic wave radiated from the radiator 3 and the wiring 8 is large in the field excitation direction of the electromagnetic wave, thus the radiated electromagnetic wave couples with the wiring 8. As a result, radiation of the electromagnetic wave from the antenna device C3 as a comparative structure is impeded, causing reduction in antenna gain.

That is to say, a wiring can be disposed in the dielectric substrate 5 because reduction in antenna gain can be suppressed by taking into consideration the field excitation direction of the electromagnetic wave radiated.

Next, the relationship between wiring of a conductor pattern provided on the same surface of the dielectric substrate 5 as the surface on which the director 6 is provided and the antenna gain will be described.

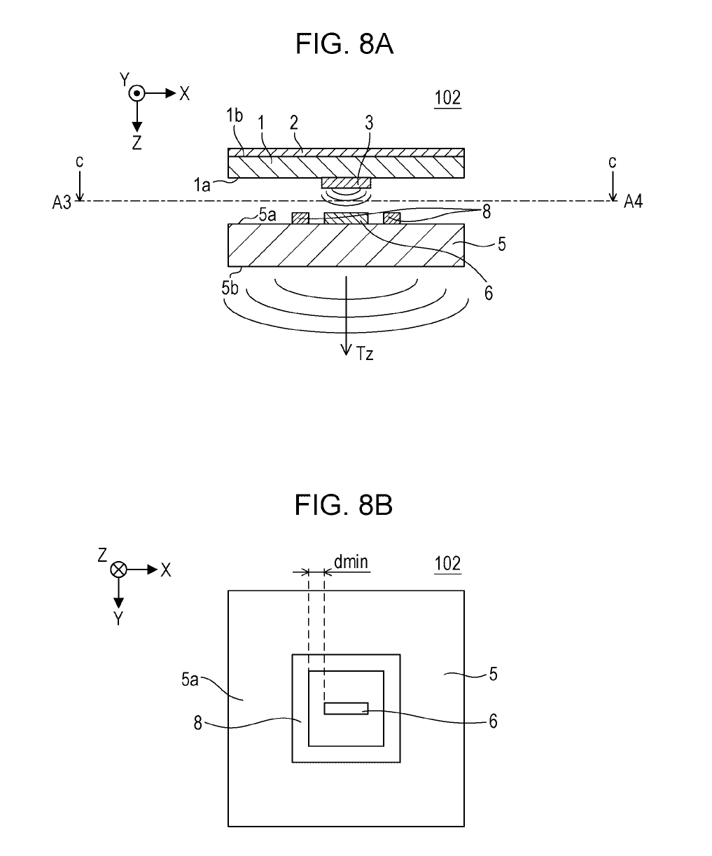

FIGS. 8A and 8B show the structure of an antenna device 102 according to the first embodiment. In FIGS. 8A and 8B, components similar to those in FIG. 2B are given the same reference characters and are not described again. In FIG. 8A, the radiation direction Tz is indicated.

FIG. 8A is a sectional view of the antenna device 102 in an X-Z plane including the radiator 3 and the director 6 as with FIG. 2B. FIG. 8B is a sectional view of the antenna device 102 in an X-Y plane taken along line A3-A4 in FIG. 8A, showing the dielectric substrate 5 as seen from the direction of arrow c in FIG. 8A (the negative direction of the Z-axis).

The antenna device 102 is different from the antenna device 100 in that it has the wiring 8.

As shown in FIG. 8A, the wiring 8 is provided on the same surface of the dielectric substrate 5 as the surface on which the director 6 is provided, that is, the surface 5a. As shown in FIG. 8B, in plan view of the dielectric substrate 5, the wiring 8 is positioned at a predetermined distance away from the director 6 and formed so as to surround the director 6. Hereinbelow, the minimum distance between the director 6 and the wiring 8 will be denoted as dmin.

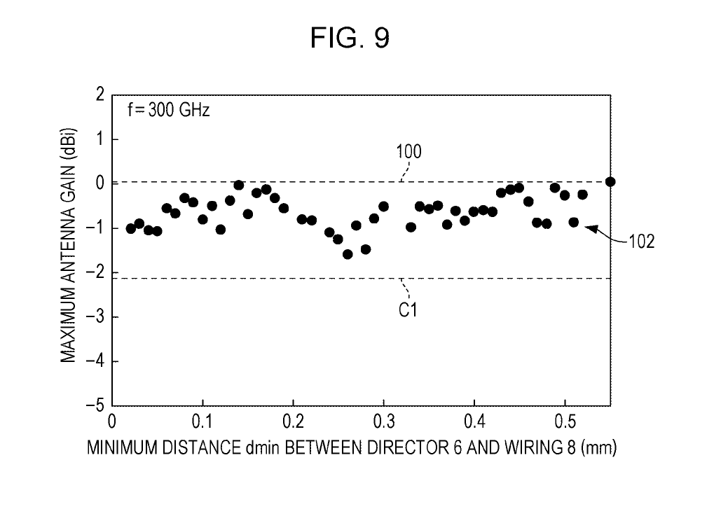

Next, the relationship between the minimum distance dmin between the director 6 and the wiring 8 and the antenna gain is described in FIG. 9.

FIG. 9 is a diagram showing the relationship between the minimum distance dmin and the maximum antenna gain. In FIG. 9, the horizontal axis represents the minimum distance dmin and the vertical axis represents the maximum antenna gain of the antenna device 102 for the minimum distance dmin when the frequency f of the electromagnetic wave radiated is 300 GHz. The maximum antenna gain of the antenna device 100 and that of the antenna device C1 as a comparative structure are also shown for comparison.

In FIG. 9, the maximum antenna gain of the antenna device 102 is larger than that of the antenna device C1 as a comparative structure whatever the value of the minimum distance dmin is. In other words, the antenna device 102 with the director 6 also can achieve a higher antenna gain than that of the antenna device C1 as a comparative structure without a director when the wiring 8 is provided on the same surface of the dielectric substrate 5 as the director 6.

Also in FIG. 9, the maximum antenna gain of the antenna device 102 varies with the minimum distance dmin. The relationship between the maximum antenna gain and the minimum distance dmin depends on the frequency of the electromagnetic wave radiated. When the wiring 8 is provided on the surface 5a, the maximum antenna gain can be improved by taking into consideration the frequency of the electromagnetic wave radiated, the minimum distance dmin, and the geometry of the wiring.

As described above, the antenna device 100 according to the first embodiment includes: a dielectric substrate 5 having a surface 5a (a first surface) and a surface 5b (a second surface); a semiconductor substrate 1 disposed above the surface 5a and having a surface 1b (a third surface) and a surface 1a (a fourth surface) that faces the dielectric substrate 5; an integrated circuit (not shown) disposed on the surface 1a of the semiconductor substrate 1; a radiator 3 disposed on the surface 1a of the semiconductor substrate 1; a reflector 2 disposed at a position where projection of the radiator 3 along a radiation direction Tz of an electromagnetic wave radiated from the radiator 3 falls on the surface 1b of the semiconductor substrate 1; and a director 6 disposed at a position where projection of the radiator 3 along the radiation direction Tz falls on the dielectric substrate 5.

This arrangement makes the radiator 3, the reflector 2, and the director 6 function as a single antenna, and the director 6 can direct the electromagnetic wave radiated from the radiator 3 into the radiation direction Tz. This reduces components radiated from the radiator 3 in the opposite direction to the radiation direction Tz (that is, from the radiator 3 to the surface 1b) and suppresses propagation loss in the semiconductor substrate 1, so that the antenna gain can be increased.

Further, the manufacturing cost can be kept low because the antenna device 100 is of a simple structure that forms the director 6, which is a passive element, on the dielectric substrate 5 by means of a conductor pattern, and no additional components other than the director 6 are required besides the semiconductor substrate 1 and the dielectric substrate 5 on which the semiconductor substrate 1 is mounted.

While the director 6 in the first embodiment was described as being provided on a surface of the dielectric substrate 5 that faces the semiconductor substrate 1 (that is, the surface 5a in FIG. 2B), the present disclosure is not limited to this. The director 6 may instead be formed from wiring metal on the surface 5b (the underside) on the opposite side of the surface of the dielectric substrate 5 facing the semiconductor substrate 1. Alternatively, when the dielectric substrate 5 is a multilayered substrate, the director 6 may be disposed in an inner layer of the dielectric substrate 5 (for example, on the inner-layer plane 5c in FIG. 5A). The position of the director 6 may be adjusted relative to the depth direction of the dielectric substrate 5 (the Z-axis direction in FIG. 2B).

By thus changing the position of the director 6, the interval between the radiator 3 and the director 6 can be adjusted also in the depth direction of the dielectric substrate 5 in addition to via the height of the bumps 4 (the length of the bumps 4 in the Z-axis direction), so that the antenna device 100 is also operable in a frequency band that is difficult to adjust with the height of the bumps 4.

### Second Embodiment

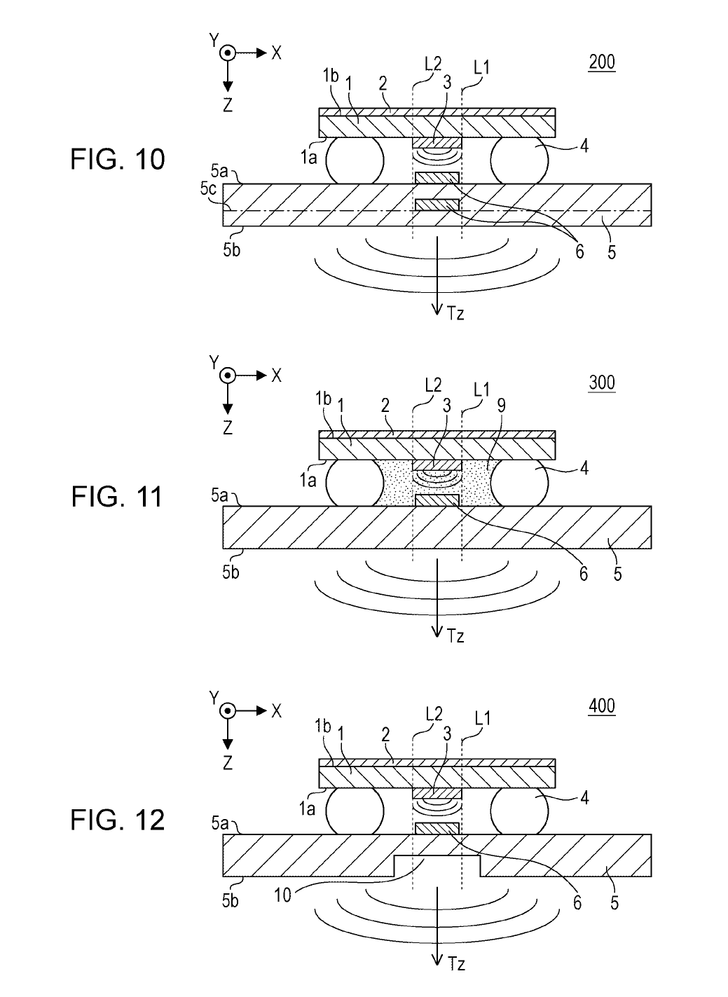

FIG. 10 shows the structure of an antenna device 200 according to a second embodiment of the present disclosure. In FIG. 10, components similar to those in FIG. 2B are given the same reference characters and are not described again.

FIG. 10 is a sectional view of the antenna device 200 in an X-Z plane including the radiator 3 and the director 6 as with FIG. 2B. As the X-Y plane in FIG. 10 is similar to the X-Y plane in FIGS. 2C and 2D, it is not described in detail again.

The antenna device 200 is different from the antenna device 100 in that it has multiple directors 6. Specifically, the directors 6 of the antenna device 200 are disposed at positions along the radiation direction Tz on the surface 5a of the dielectric substrate 5 that faces the semiconductor substrate 1 as well as on the inner-layer plane 5c of the dielectric substrate 5 along the radiation direction Tz, for example.

By making the dielectric substrate 5 from a multilayered substrate, the director 6 can be disposed on the inner-layer plane 5c using the wiring metal on the inner-layer plane 5c.

In the antenna device 200, the radiator 3, the reflector 2, and the two directors 6 function as a single antenna. With two directors 6, the antenna device 200 is able to direct more of the electromagnetic wave radiated from the radiator 3 in the radiation direction Tz than with a single director 6. This reduces components radiated from the radiator 3 in the opposite direction to the radiation direction Tz and suppresses propagation loss in the semiconductor substrate 1, so that the directivity and the antenna gain can be increased.

While the two directors 6 in the second embodiment are described as being disposed on the surface 5a of the dielectric substrate 5 that faces the semiconductor substrate 1 and on the inner-layer plane 5c of the dielectric substrate 5, the present disclosure is not limited to this. For example, both of the two directors 6 may be disposed in an inner layer of the dielectric substrate 5. Alternatively, for example, one of the directors 6 may be disposed on the surface 5b (the underside) of the dielectric substrate 5 on the opposite side of the surface 5a facing the semiconductor substrate 1, and the other director 6 may be disposed on either the surface 5a of the dielectric substrate 5 that faces the semiconductor substrate 1 or the inner-layer plane 5c. There may be three or more directors 6.

### Third Embodiment

FIG. 11 shows the structure of an antenna device 300 according to a third embodiment of the present disclosure. In FIG. 11, components similar to those in FIG. 2B are given the same reference characters and are not described again.

FIG. 11 is a sectional view of the antenna device 300 in an X-Z plane including the radiator 3 and the director 6 as with FIG. 2B. As the X-Y plane in FIG. 11 is similar to the X-Y plane in FIGS. 2C and 2D except that an underfill 9 discussed later is placed around the radiator 3 and the director 6, it is not described in detail again.

The antenna device 300 is different from the antenna device 100 in that the underfill 9 is placed between the semiconductor substrate 1 and the dielectric substrate 5. When four bumps 4 are provided as shown in FIG. 2D, the underfill 9 is placed in a region in which the bumps 4 are not present within the dotted box in FIG. 2D, for example.

The underfill 9 is a medium having a relative dielectric constant εᵣ (εᵣ being 1 or higher). The underfill 9 may have gaps in some parts of it. The effective wavelength λ_{eff} inside the underfill 9 relative to the wavelength in vacuum, λ₀, is represented by Equation (1) below using the relative dielectric constant εᵣ.

λ_{eff}=λ₀/\sqrt{εᵣ} (1)

This means that placement of the underfill 9 having the relative dielectric constant εᵣ of 1 or higher shortens the effective wavelength λ_{eff} inside the underfill 9, permitting a shortened interval between the director 6 and the radiator 3.

With the structure of FIG. 11, the antenna device 300 can be made compact even when it radiates an electromagnetic wave with a relatively long wavelength, and also it is operable with a relatively low frequency.

The third embodiment may be combined with at least one of the other embodiments. For example, the underfill 9 may be placed between the semiconductor substrate 1 and the dielectric substrate 5 in the antenna device 200 according to the second embodiment.

### Fourth Embodiment

FIG. 12 shows the structure of an antenna device 400 according to the fourth embodiment of the present disclosure. In FIG. 12, components similar to those in FIG. 2B are given the same reference characters and are not described again.

FIG. 12 is a sectional view of the antenna device 400 in an X-Z plane including the radiator 3 and the director 6 as with FIG. 2B. As the X-Y plane in FIG. 12 is similar to the X-Y plane in FIGS. 2C and 2D, it is not described in detail again.

The antenna device 400 is different from the antenna device 100 in that it has a cavity 10 in the dielectric substrate 5.

The cavity 10 is a recess in the dielectric substrate 5. The cavity 10 is a recess formed by cutting away a part of the dielectric substrate 5 from the surface 5b in the negative direction of the Z-axis by a length less than the thickness of the dielectric substrate 5, for example. The cavity 10 is such a region that covers the entire area of the director 6 when the dielectric substrate 5 is seen in plan view (in the X-Y plane), for example.

With this structure, the antenna device 400 can decrease the propagation loss of an electromagnetic wave in the dielectric substrate 5 and thus can increase the antenna gain.

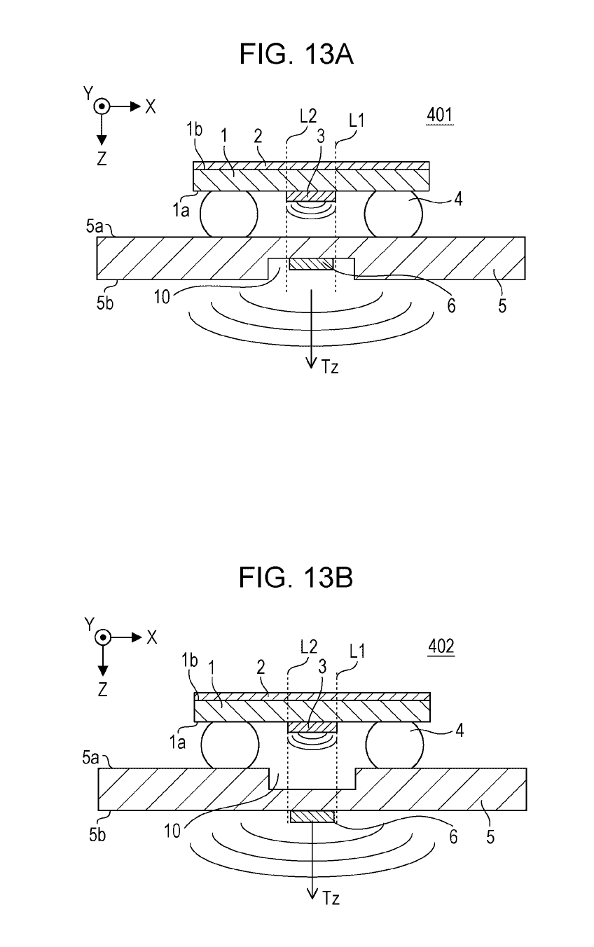

While the cavity 10 of the antenna device 400 was described as being disposed immediately below the director 6, the present disclosure is not limited to this. For example, the director 6 may instead be disposed inside the cavity 10 or the director 6 may be disposed inside the dielectric substrate 5. Variations of the antenna device 400 according to the fourth embodiment will be described below with reference to FIGS. 13A and 13B.

FIG. 13A shows an exemplary variation of the antenna device 400 according to the fourth embodiment. FIG. 13B shows another exemplary variation of the antenna device 400 according to the fourth embodiment of the present disclosure. In FIGS. 13A and 13B, components similar to those in FIG. 12 are given the same reference characters and are not described again.

FIG. 13A is a sectional view of the antenna device 401 in an X-Z plane including the radiator 3 and the director 6 as with FIG. 2B. As the X-Y plane in FIG. 13A is similar to the X-Y plane in FIGS. 2C and 2D except that the director 6 is not disposed on a surface of the dielectric substrate 5, it is not described in detail again.

As opposed to the antenna device 400, the director 6 of the antenna device 401 is disposed inside the cavity 10 rather than on a surface of the dielectric substrate 5 (the surface 5a).

With this structure, the antenna device 401 can decrease the propagation loss of an electromagnetic wave in the dielectric substrate 5 and thus can increase the antenna gain similarly to the antenna device 400.

While the cavity 10 of the antenna device 400 was described as being formed by cutting away a part of the dielectric substrate 5 from the surface 5b in the negative direction of the Z-axis by a length less than the thickness of the dielectric substrate 5, the present disclosure is not limited to this. For example, the cavity 10 may instead be formed by cutting away a part of the dielectric substrate 5 from the surface 5a in the positive direction of the Z-axis by a length less than the thickness of the dielectric substrate 5. When the cavity 10 is formed in this manner, the director 6 may be provided below the cavity 10 and inside the dielectric substrate 5, or alternatively on the surface 5b, for example.

FIG. 13B is a sectional view of the antenna device 402 in an X-Z plane including the radiator 3 and the director 6 as with FIG. 2B. The antenna device 402 of FIG. 13B illustrates a case where the cavity 10 is formed by cutting away a part of the dielectric substrate 5 from the surface 5a in the positive direction of the Z-axis by a length less than the thickness of the dielectric substrate 5, and the director 6 is provided on the surface 5b.

The fourth embodiment may be combined with at least one of the other embodiments. For instance, the antenna device 300 according to the third embodiment may have the cavity 10 on the dielectric substrate 5 at a position immediately below the director 6 along the radiation direction Tz.

### Fifth Embodiment

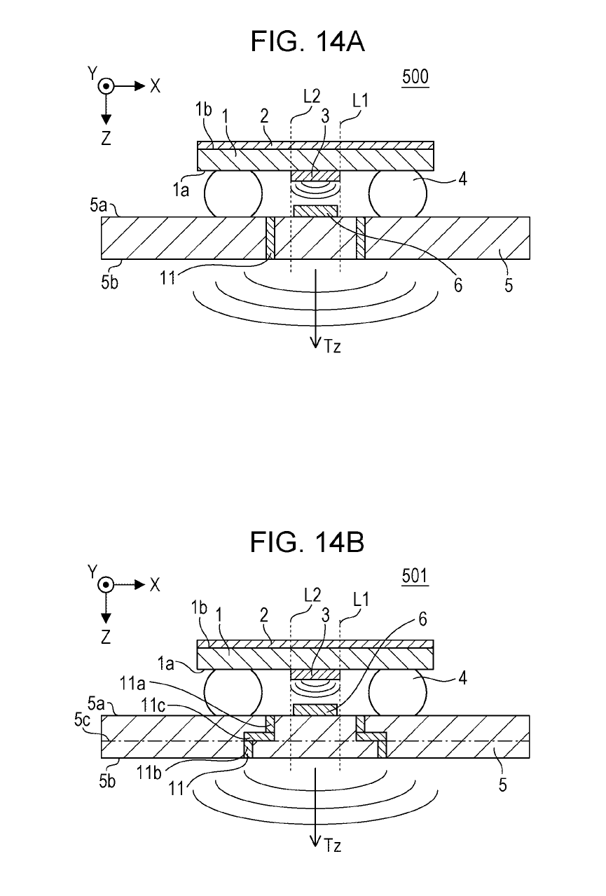

FIG. 14A shows the structure of an antenna device 500 according to a fifth embodiment of the present disclosure. In FIG. 14A, components similar to those in FIG. 2B are given the same reference characters and are not described again.

FIG. 14A is a sectional view of the antenna device 500 in an X-Z plane including the radiator 3 and the director 6 as with FIG. 2B. As the X-Y plane in FIG. 14A is similar to the X-Y plane in FIGS. 2C and 2D except that a via 11 discussed below is disposed in it, it is not described in detail again.

The antenna device 500 is different from the antenna device 100 in that the two vias 11 are disposed around the director 6.

Each of the two vias 11 is disposed so as to surround the director 6 at a position a first distance away from the director 6. Each of the two vias 11 is a through via formed between the surface 5a and the surface 5b of the dielectric substrate 5.

Such a structure gives each of the two vias 11 a similar function to that of a metal wall of a waveguide running along the radiation direction Tz in the dielectric substrate 5; thus the directivity can be varied so that the electromagnetic wave re-radiated from the director 6 proceeds in the radiation direction Tz.

When multiple radiators are disposed on the semiconductor substrate and directors corresponding to them are disposed on the dielectric substrate, positioning of the two vias 11 between neighboring directors enables separation of the electromagnetic waves re-radiated by the directors.

The fifth embodiment may be combined with at least one of the other embodiments. For example, the antenna device 400 according to the fourth embodiment may have the two vias 11 positioned so as to surround the director 6.

While each of the vias 11 in the fifth embodiment was described as being a through via, the present disclosure is not limited to this. For example, each of the vias 11 may instead be a via formed in a step-like configuration with combination of a stacked via and wiring as shown in FIG. 14B. Although the stacked via 11 in the example described below is two-level, this is not limitation and the stacked via 11 may be three-level or more. FIG. 14B shows an exemplary variation of the antenna device 500 according to the fifth embodiment of the present disclosure. FIG. 14B is a sectional view of the antenna device 501 in an X-Z plane including the radiator 3 and the director 6 as with FIG. 2B. In FIG. 14B, the via 11 is provided inside the dielectric substrate 5. In the example described below, the via 11 is formed of a first via 11a, a second via 11b, and a inner layer wiring 11c.

The first via 11a is formed from the surface 5a in the positive direction of the Z-axis with a length less than the thickness of the dielectric substrate 5. The second via 11b is formed from the surface 5b in the negative direction of the Z-axis with a length less than the thickness of the dielectric substrate 5. The position of the second via 11b on the X-axis is different from the position of the first via 11a on the X-axis. The inner layer wiring 11c is a via connecting between the first via 11a and the second via 11 b and positioned on the inner-layer plane 5c of the dielectric substrate 5.

Such a structure gives the via 11 a similar function to that of a metal wall of a waveguide with its opening area increasing as it goes away from the director 6 along the radiation direction Tz in the dielectric substrate 5; thus the directivity can be varied more sharply than the structure of FIG. 14A so that the electromagnetic wave re-radiated from the director 6 proceeds in the radiation direction Tz. The level of the via is not limited to two-level as shown.

The above-described embodiments may be employed in combination as desired.

Although the antenna devices described in the above embodiments have a single radiator 3, they may have more than one radiator.

Also, although the radiator 3 in the above embodiments was described as being a dipole, the present disclosure is not limited to this. The radiator 3 may be in the form of other planner antennas.

While various embodiments have been described above with reference to the drawings, the present disclosure is not limited to those embodiments, of course. It would be appreciated by those skilled in the art that various variations or modifications may be conceived within the scope of the claims and such variations or modifications naturally fall within the technical scope of the present disclosure. Further, components from the above-described embodiments may be combined in any manner without departing from the gist of the disclosure.

### <Overview of the Present Disclosure>

An antenna device according to the present disclosure includes: a dielectric substrate having a first surface and a second surface; a semiconductor substrate disposed above the first surface of the dielectric substrate and having a third surface and a fourth surface that faces the dielectric substrate; an integrated circuit disposed on the fourth surface of the semiconductor substrate; a radiator disposed on the fourth surface of the semiconductor substrate; a reflector disposed at a position where projection of the radiator along a radiation direction of an electromagnetic wave radiated from the radiator falls on the third surface of the semiconductor substrate; and one or more directors disposed at a position where projection of the radiator along the radiation direction falls on the dielectric substrate.

In the antenna device according to the present disclosure, the director is disposed on the dielectric substrate at two or more positions.

In the antenna device according to the present disclosure, a medium having a relative dielectric constant of 1 or higher is disposed in at least part of a space between the dielectric substrate and the semiconductor substrate.

In the antenna device according to the present disclosure, the dielectric substrate has a cavity at a position where projection of the radiator along the radiation direction falls.

In the antenna device according to the present disclosure, the director is disposed inside the cavity.

In the antenna device according to the present disclosure, the dielectric substrate has a via surrounding the director at a position a first distance away from the director.

In the antenna device according to the present disclosure, the dielectric substrate has a wiring extending in a short direction of the radiator.

In the antenna device according to the present disclosure, a wiring is disposed on the first surface of the dielectric substrate, and a minimum distance between the wiring and the director is determined at least based on a frequency of the electromagnetic wave.

In the antenna device according to the present disclosure, at least part of the integrated circuit performs signal processing on a signal of a frequency from 50 GHz to 10 THz, inclusive.

In the antenna device according to the present disclosure, an interval between the radiator and the director is from ⅛ to ¼ of a wavelength of the electromagnetic wave.

The present disclosure can be implemented as software, hardware, or software that operates in conjunction with hardware.

Some of the functional blocks used in the description of the embodiments above may be implemented in an integrated circuit (IC) and the processes described in the embodiments may be partially or entirely controlled by a single IC or a combination of ICs. The ICs may be individual chips or a single chip that includes some or all of the functional blocks. The ICs may have data input and output. An IC may be called an large scale integration (LSI), a system LSI (or custom LSI), a very large scale integration (VLSI), an ultra large scale integration (ULSI), or a wafer scale integration (WSI) depending on difference in the application, form, and degree of integration.

An IC may be implemented as a dedicated circuit, a general-purpose processor, or a dedicated processor. A field programmable gate array (FPGA), which can be programmed after IC fabrication, or a reconfigurable processor permitting reconfiguration of connections and settings of circuit cells within an IC may be also employed. The present disclosure may be implemented as a digital process or an analog process.

Moreover, if an integrated circuit technology to replace existing ICs or LSIs emerges with advancement in semiconductor technology or other derivative techniques, such a technology could be used for integration of functional blocks, of course. Application of biotechnology is conceivable, for example.

The antenna device according to the present disclosure is applicable to transceiver modules that perform wireless communication in a radar system or a communication system.

What is claimed is:

1. An antenna device comprising:
a dielectric substrate having a first surface and a second surface;
a semiconductor substrate disposed above the first surface of the dielectric substrate and having a third surface and a fourth surface that faces the dielectric substrate;
an integrated circuit disposed on the fourth surface of the semiconductor substrate;
a radiator disposed on the fourth surface of the semiconductor substrate;
a reflector disposed at a position where projection of the radiator along a radiation direction of an electromagnetic wave radiated from the radiator falls on the third surface of the semiconductor substrate; and
one or more directors disposed at a position where projection of the radiator along the radiation direction fall on the dielectric substrate.

2. The antenna device according to claim 1, wherein the one or more directors comprise a plurality of directors, the plurality of directors being disposed on the dielectric substrate at different positions.

3. The antenna device according to claim 1, wherein a medium having a relative dielectric constant of 1 or higher is disposed in at least part of a space between the dielectric substrate and the semiconductor substrate.

4. The antenna device according to claim 1, wherein the dielectric substrate has a cavity at a position where projection of the radiator along the radiation direction falls.

5. The antenna device according to claim 4, wherein the one or more directors are disposed inside the cavity.

6. The antenna device according to claim 1, wherein the dielectric substrate has a via surrounding the one or more directors at a position a first distance away from the one or more directors.

7. The antenna device according to claim 1, wherein the dielectric substrate has a wiring extending in a short direction of the radiator.

8. The antenna device according to claim 1, wherein
a wiring is disposed on the first surface of the dielectric substrate, and
a minimum distance between the wiring and the one or more directors are determined at least based on a frequency of the electromagnetic wave.

9. The antenna device according to claim 1, wherein at least part of the integrated circuit performs signal processing on a signal of a frequency from 50 GHz to 10 THz, inclusive.

10. The antenna device according to claim 1, wherein an interval between the radiator and the one or more directors are from ⅛ to ¼ of a wavelength of the electromagnetic wave.
